(19) United States
(12) Patent Application Publication
(10) Pub. No.: US 2003/0058675 A1
(43) Pub. Date: Mar. 27, 2003

(54) Silicon-on-insulator SRAM cells with increased stability and yield

(75) Inventors: Anthony Gus Aipperspach, Austin, TX (US); Andres Bryant, Essex Junction, VT (US); Todd Alan Christensen, Rochester, MN (US); Dennis T. Cox, Rochester, MN (US); Jerome Brett Lasky, Essex Junction, VT (US); John Edward Sheets II, Zumbrota, MN (US); Francis Roger White, Essex Junction, VT (US)

Correspondence Address: Robert R. Williams, IBM Corporation, Dept. 917, 3605 Highway 52 North, Rochester, MN, 55901-7829, US

(73) Assignee: INTERNATIONAL BUSINESS MACHINES CORPORATION, ARMONK, NY

(21) Appl. No.: 09/962,403

(22) Filed: Sep. 25, 2001

(51) Int. Cl. G11C 5/06; G11C 5/02

(52) U.S. Cl. 365/63; 365/154; 365/51

(57) ABSTRACT

An SRAM memory cell made with increased stability using SOI technology is provided. Increased stability occurs because of raising the threshold voltage of the transfer nfets connected to the word line. Preferably the increase of threshold voltage is achieved using boron ion implantation.

### FIELD OF THE INVENTION

The present invention relates generally to the field of static random access memory (SRAM) cells and more specifically relates to increasing the stability of semiconductor-on-insulator, especially silicon-on-insulator (SOI), SRAM cells by raising the threshold voltage of certain transistors comprising the cell.

### BACKGROUND OF THE INVENTION

Metal Oxide Semiconductor Field Effect Transistor (MOSFET) scaling on bulk silicon has been the primary focus of the semiconductor and microelectronic industry for achieving Complementary Metal Oxide Semiconductor (CMOS) chip performance and density objectives. The shrinking of MOSFET dimensions for high density, low power and enhanced performance requires reduced power supply voltages. Because power consumption is a function of capacitance, voltage, and transition frequency, the focus has been on reducing both the capacitance and the voltage as the operating or switching frequency increases. As a result, dielectric thickness and channel length are scaled with power supply voltage. Power supply reduction continues to be the trend for future low voltage CMOS, however, transistor performance is severely impacted by both junction capacitance and the MOSFET body effect at these lower voltages. As technologies scale below 0.25 μm channel lengths, to 0.15 μm and 0.1 μm and shorter, short channel effects, gate resistance, channel profiling and other barriers become an issue for advanced CMOS technologies. While significant success has been achieved with successive scaling of bulk CMOS technology, the manufacturing control issues and power consumption become increasingly difficult.

Silicon-on-insulator (SOI) technology is an enhanced silicon technology in which an insulating layer is situated above the bulk CMOS layer. SOI transistors are built in a thin layer of silicon on top of this buried insulator, typically silicon oxide, with bulk silicon below the buried insulator. Using SOI technology eliminates many of the concerns and obstacles of bulk silicon CMOS at low power supply voltages. SOI has significant advantages over bulk CMOS technology and achieves the scaling objectives of low power and high switching frequency. Naming only some of the technology benefits offered by SOI: SOI provides low power consumption, low leakage current, low capacitance diode structures, good sub-threshold IV (current/voltage) characteristics, a low soft error rate from both alpha particles and cosmic rays, and good SRAM access times. Because of these characteristics, SOI technology is especially useful in portable and wireless applications.

Standard advanced semiconductor technologies map into SOI technology without significant modifications. SOI process techniques include epitaxial lateral overgrowth, lateral solid-phase epitaxy and full isolation by porous oxidized silicon. SOI networks can be constructed using the semiconductor process of techniques of separation by implanted oxygen and wafer-bonding and etch-back because they achieve low defect density, thin film control, good minority carrier lifetimes and good channel mobility characteristics. Structural features are defined by shallow trench isolation. Shallow trench isolation eliminates planarity concerns and multidimensional oxidation effects, thereby allowing technology migration and scaling to sub-0.25 μm technologies.

FIG. 1 illustrates a cross section through the length of a traditional SOI transistor 100. The SOI transistor 100 has a polysilicon gate 110 over a thin silicon dioxide layer 112. Source (drain) 114 and a drain (source) 116 are built over a buried insulative oxide 130 which is on top of a bulk silicon substrate 140. Between the source (drain) 114 and the drain (source) 116 and above the buried insulative oxide 130 is the floating body 120. On the outer sides of the source (drain) 114 and the drain (source) 116 are isolation oxides 118 to prevent a transistor from being electrically connected to another transistor. The buried insulative oxide layer 130 reduces the diffusion parasitic capacitance and the resulting floating body lowers the threshold voltage of the transistor, which, in turn, increases the performance of the SOI transistors. The voltage of the floating body 120, however, varies over time as it eventually leaks to Vdd or to some ground voltage which in turn causes the threshold voltage of the transistor 100 to also vary. The floating body effects were at first considered beneficial because of the increased speed at which a transistor can switch, but performance could not be predicted using transistors in which the bodies were allowed to float. Floating body transistors, moreover, are extremely sensitive to nonperfect input voltage on the gates and to noise. Because of this sensitivity and hysteresis, i.e., “history effects” meaning that the voltage on the floating body is dependent upon previous cycles and the time durations of the cyclic input, floating body transistors are difficult to match. For instance, a high signal immediately after two or three other high signals might be fast to synchronize with other signals. Similarly, a low signal immediately after two or three high signals might be too slow.

These floating body effects are especially noticeable in SRAM cells which require the transistors to hold their values and to be reproducibly responsive to the same voltages during high frequency clocking cycles. FIG. 2a is a traditional SRAM cell 200 in which the feedback from the output of one inverter is the input to the other inverter, i.e., cross-coupled inverters; this arrangement stabilizes the state of the SRAM. An inverter comprises a n-type field effect transistor (nfet) 250 (270) having an input and output connected to the gate and drain of a p-type field effect transistor (pfet) 240 (260). The gates of nfets 230 and 280 are connected to a word line 220 and pass the data into and out of the memory cell 200 and are hence referred to as pass devices or transfer devices. The sources of the pass nfets 230 and 280 are connected to the bit line complement 210 and true 290, respectively. Cross-coupling of the two inverters is achieved by connecting the drains of nfet 270 and pfet 260 with the gates of pfet 240 and nfet 250 and, similarly, the drains of nfet 250 and pfet 240 are connected to the gates of pfet 260 and nfet 270. There is a symmetry to the cell in that pfets 240 and 260 are matched, as are nfets 230 and 280; and nfet 250 is matched with nfet 270. To store a value of 01 in the memory cell 200, nfet 250 and pfet 260 would both be turned on; whereas to store a value of 10 in the memory cell nfet 270 and pfet 240 would both be turned on. By convention, it is the value of the “true” side which is the stored value.

Small mismatches in the devices during processing can cause the cell to favor one of the states, either a “1” or a “0.” Mismatches result from dislocations between the drain and floating body and between the floating body and the source or from metal precipitates forming during the actual growth and processing of the transistors. These dislocations may locally increase voltage leakage of the floating body to/from the source or drain thus, depending upon the location of the defect, lowering or raising the potential of the floating body. Switching history and its effect on the SOI floating bodies of the transistor, moreover, also contribute to differences in voltages of devices designed to be symmetric. In a memory cell, when a word line is on, a value of 0 is really between Vdd and ground, and a value of 1 is not actually at Vdd but somewhere between Vdd and ground. Anytime a word line is on and the bit line is held or precharged to Vdd, such as during a half-select or read operation, the zero voltages may increase to the point that the cell can inadvertently flip state resulting in stability failure.

FIG. 2b shows the history and floating body effects within the memory cell of FIG. 2a. The bottom nfet 250 can be weaker relative to the average or starting condition than it was designed to be while the pass nfet 230 becomes stronger. The labeling of “strong” and “weak” qualitatively refers to the floating body effects which degrades the stability of the cell because of past switching history. To accommodate these effects, the sizes of the transistors may be changed so that a weak nfet may be designed to be larger and a strong nfet made be designed to be smaller. Thus, nfet 250 may be designed to be larger and stronger and pass nfet 230 may be intentionally designed to be smaller and weaker. In fact, improving the stability of SRAM cells has been traditionally accomplished by changing the transistor device width/length ratios. Many of the transistors, however, are already at or near their minimum dimensions for the technology and making the transistors smaller is not feasible.

There still is a need in the industry, however, to compensate for floating body effects which cause memory cell stability failures without changing the sizes and hence, the designs, of individual transistors.

### SUMMARY OF THE INVENTION

A principal object of the present invention is to provide a SRAM memory cell with increased stability and yield. This invention is achieved in a SRAM memory cell, comprising at least one transfer nfet connected to a word line having a threshold voltage higher than other transistors within the memory cell. At least one nfet of an inverter within the memory cell may also have an increased threshold voltage. A key feature, however, is that the other transistors in the memory cell do not have an increased threshold voltage. The memory cell may be made from bulk silicon, or from a semiconductor-on-insulator technology.

The semiconductor-on insulator technology may be a silicon-on-insulator technology and the insulator may be silicon dioxide. Alternatively, the insulator may be sapphire. The higher threshold voltage may be achieved during manufacture by boron or indium ion implantation prior to definition of a gate of the transfer nfet(s) connected to the word line. Alternatively, the higher threshold voltage may be achieved with an increased thickness of a gate oxide layer above a floating body of the transfer nfet(s).

It is further contemplated that the semiconductor-on-insulator technology may include from semiconductors of Group III, V and/or from Group II, VI of the periodic chart.

The invention may also be considered a SRAM memory cell having increased stability, comprising: a word line; a true bit line; a complement bit line; a first transfer nfet connected to the word line, the first transfer nfet having a higher threshold voltage than other transistors in the memory cell; a first inverter comprising a pfet and an nfet whose gates and drains are connected; a second transfer nfet whose gate is connected to the word line, the second transfer nfet having a higher threshold voltage than other transistors in the memory cell; and a second inverter comprising a second pfet and a second nfet whose gates and drains are connected; wherein the first and second inverter are cross-coupled to the output of the second and first transfer nfets, respectively. The first and second transfer nfet devices may be silicon-on-insulator (SOI) transistors whose threshold voltage was increased using boron or indium ion implantation. Alternatively, the threshold voltage of the first and second transfer nfet devices may be increased with an increased thickness of a gate oxide layer above a floating body. Additionally, the nfet of the first inverter and the second nfet of the second inverter may also have increased threshold voltages above the threshold voltages of other remaining transistors in the SRAM memory cell.

The invention may also be considered a semiconductor memory cell for use in memory arrays, comprising a means to receive a word line signal; a means to receive a true bit line signal; a means to receive a complement bit line signal; a means to cross-couple a first inverter connected to the means to receive the true bit line signal with a second inverter connected to the means to receive a complement bit line signal; and a means to increase the stability of the means to receive the word line signal. The means to receive a word line signal may comprise two transfer nfets, each of which are connected to a word line; the output of first transfer nfet connected to the input of the second inverter and the output of the second transfer nfet connected to the input of the first inverter; and the means to increase the stability of the means to receive the word line signal comprises increasing the threshold voltage of the two transfer nfets. There may also be means to increase the threshold voltage of two pulldown nfets, the first pulldown nfet included in the first inverter and the second pulldown nfet included in the second inverter. The means to increase the threshold voltage of the nfets may comprise implantation of boron ions into a region below a gate of each nfet and between a source and a drain of each nfet prior to gate definition without increasing the threshold voltage of any other fets in the semiconductor memory.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 illustrates a conventional SOI transistor;

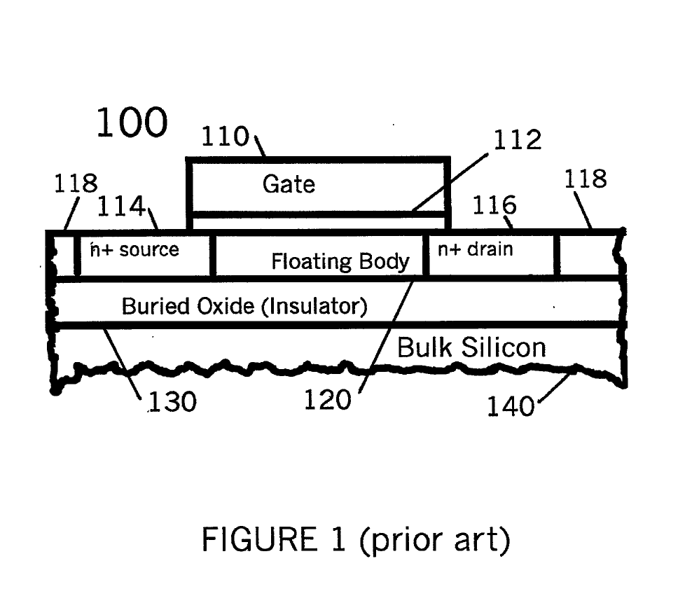

FIG. 2a is a circuit diagram of a SRAM cell;

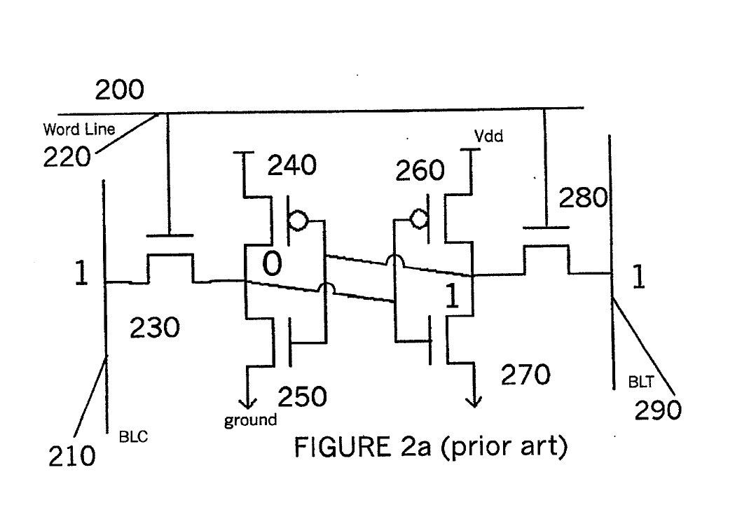

FIG. 2b is the circuit diagram of FIG. 2a showing the strength or weaknesses of the floating body effects.

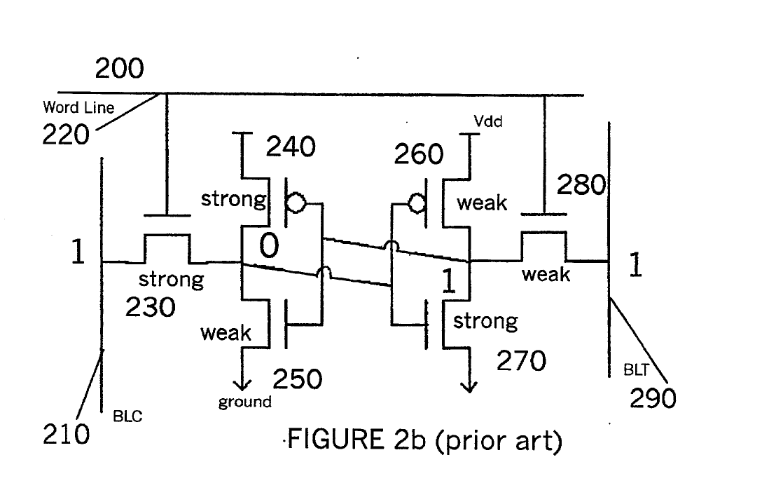

FIG. 3 is a mask diagram of a SRAM cell in accordance with a preferred embodiment of the invention. It is suggested that FIG. 3 be printed on the face of the patent.

### DETAILED DESCRIPTION OF THE PREFERRED EMBODIMENTS

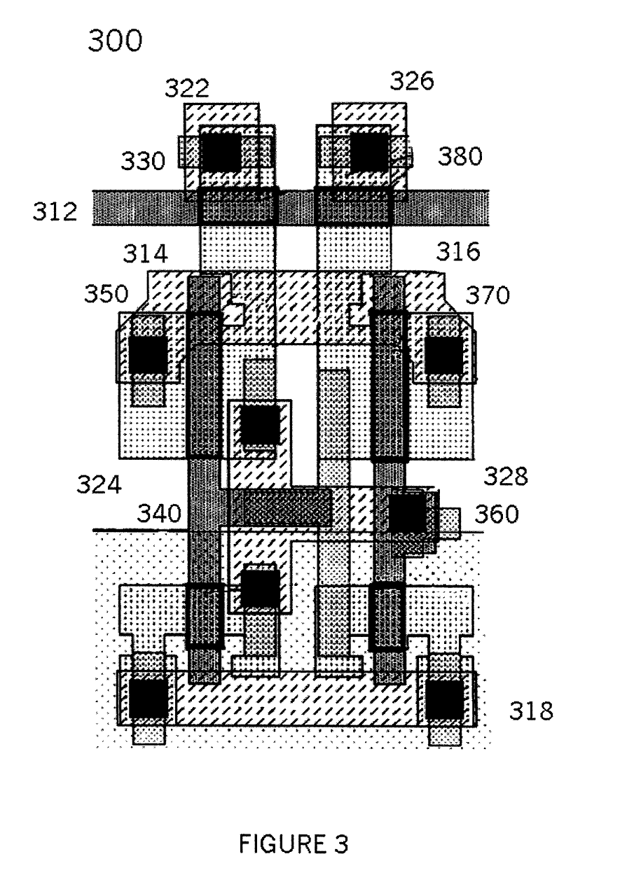

Having reference now to the Drawing, in FIG. 3 therein is shown a SRAM memory cell in accordance with an embodiment of the invention. In the preferred embodiment, those nfets susceptible to floating body effects have an additional mask of ion implantation which increases the threshold voltage of the transistor. FIG. 3 shows the six transistors embodied in an SRAM cell. The two transfer nfets 330 and 380 are shown with the gate 312, and a diffusion area 314 as a source/drain. The two pulldown nfets 350 and 370 are connected to ground 316, and the two pullup pfets 340 and 360 are shown connected to Vdd 318. It will be understood by one skilled in the art that pfets 340 and 360 may be replaced with resistors. Area 322 is a first metal layer; darker area 324 is a polysilicon area, contacts 326 are shown as the black areas; and a local interconnect 328 behaves as a metal layer connection between the polysilicon areas 324 or diffusion areas 314 to the first metal layer 322.

In an embodiment of the invention, the threshold voltages of nfets 330, 380, 350 and 360 are increased using ion implantation. Preferably, however, the threshold voltages of only the transfer or pass nfets 330 and 380 are increased with an appropriate implantation of boron. This increase in threshold voltage improves the pfet to nfet ratio and furthermore, allows more flexibility to improve the nfet to nfet ratio. Because of the proximity of the nfets and ease of processing, all four nfets in the memory cell could be made to have an increased threshold voltage, but it is important that the implantation or other technique to increase the threshold voltages of the transfer or pass nfets and the pull down nfets not affect the other transistors in the memory cell and proximity. It is further known that selectively increasing the gate oxide thickness of the nfets will also increase the threshold voltages, but ion implantation is preferred because increasing gate oxide thicknesses increases process complexity and is more difficult to manufacture.

While the preferred embodiment is presented as using boron ion implantation into SOI transfer nfets, it is to be understood that the stability of memory cells using any semiconductor technology on any insulator can be enhanced by increasing the threshold voltage of the transfer or pass devices. Thus, the inventive concepts herein apply also to sapphire-on-silicon technology. It is also known that indium as well as boron may increase the threshold voltage of silicon transistors. Moreover, one of skill in the art will appreciate that the techniques to increase the threshold voltage and improve the stability of the memory cell can be implemented in indium phosphide, gallium arsenide, germanium, and other Group III, V and Group II, VI semiconductor technologies. Improving the threshold voltage by ion implantation is not limited to semiconductor-on-insulator devices only, but also is applicable to transistors manufactured using bulk silicon technology.

Modifying the threshold voltage characteristics of a transistor has been well understood and it is known in the art how to adjust the threshold voltage with ion implantation. For threshold voltage control, the dose is typically in the order 10¹² atoms per square centimeter and the projected range is typically less than a micron below the silicon surface. The implantation preferably occurs prior to gate definition. Boron is preferred but indium may also be used to increase the threshold voltage of the selected nfets. After implantation, a short annealing treatment may be necessary to ensure that the implanted dopant atoms are located in substitutional sites where they act as donors or acceptors, and also to restore the crystal quality. Various materials such as photoresist, metal, or oxide may be used as a mask to prevent ions from entering selected regions of the wafer. If positive photoresist is used, it is applied to the entire wafer, then light impinges on the areas of the nfets whose threshold voltages are to be raised. The photoresist blocks the implantation except where the light penetrated the photoresist. Additional factors to consider and materials for ion implantation to adjust the threshold voltage of various semiconductors are set forth in, e.g., Trapp, Blanchard, Lopp, and Kamins, The Semiconductor Technology Handbook, Technology Associates 1985 pp. 7.1, 7.1, and 12.1; and El-Kareh and Bombard, Introduction to VLSI Silicon Devices, Kluwer Academic Publishers 1986, pp. 464-473.

Thus, it has been discovered that raising the threshold voltages of the transfer nfet devices in a SRAM cell decreases the cell's sensitivity to small defects. This in turn greatly decreases the number of stability failures which in turn increases the yield. Raising the threshold voltage can be best accomplished using boron ion implantation of the floating body above the buried oxide layer prior to gate, source, and drain definition. Thus, while the present invention has been described with reference to the details of the embodiments of the invention shown in the drawing, these details are not intended to limit the scope of the invention as claimed in the appended claims.

What is claimed is:

1. A SRAM memory cell, comprising at least one transfer nfet connected to a word line having a threshold voltage higher than other transistors within the memory cell.

2. The SRAM memory cell of claim 1, further comprising at least one nfet of an inverter within the memory cell also having an increased threshold voltage.

3. The SRAM memory cell of claim 1, wherein the memory cell is made from bulk silicon.

4. The SRAM memory cell of claim 1, wherein the memory cell is made from semiconductor-on-insulator technology.

5. The SRAM memory cell of claim 4, wherein the semiconductor-on insulator technology is silicon-on-insulator technology and the insulator is silicon dioxide.

6. The SRAM memory cell of claim 4, wherein the semiconductor-on-insulator technology is silicon-on-insulator technology and the insulator is sapphire.

7. The SRAM memory cell of claim 1, wherein the higher threshold voltage is achieved during manufacture by boron ion implantation prior to definition of a gate of the at least one transfer nfet connected to the word line.

8. The SRAM memory cell of claim 1, wherein the higher threshold voltage is achieved during manufacture by indium ion implantation prior to definition of a gate of the at least one transfer nfet connected to the word line.

9. The SRAM memory cell of claim 4, wherein the higher threshold voltage is achieved with an increased thickness of a gate oxide layer above a floating body of the at least one transfer nfet.

10. The SRAM memory cell of claim 4, wherein the semiconductor-on-insulator technology is from semiconductors of Group III, V.

11. The SRAM memory cell of claim 4, wherein the semiconductor-on-insulator technology if from semiconductors of Group II, VI.

12. A SRAM memory cell having increased stability, comprising:
(a) a word line;
(b) a true bit line;
(c) a complement bit line;
(d) a first transfer nfet connected to the word line, the first transfer nfet having a higher threshold voltage than other transistors in the memory cell;
(e) a first inverter comprising a pfet and an nfet whose gates and drains are connected;
(f) a second transfer nfet whose gate is connected to the word line, the second transfer nfet having a higher threshold voltage than other transistors in the memory cell; and
(g) a second inverter comprising a second pfet and a second nfet whose gates and drains are connected;
wherein the first and second inverter are cross-coupled to the output of the second and first transfer nfets, respectively.

13. The SRAM memory cell of claim 12, wherein the first and second transfer nfet devices are silicon-on-insulator (SOI) transistors whose threshold voltage was increased using boron ion implantation.

14. The SRAM memory cell of claim 12, wherein the first and second transfer nfet devices are SOI transistors whose threshold voltage was increased with an increased thickness of a gate oxide layer above a floating body.

15. The SRAM memory cell of claim 12, wherein the nfet of the first inverter and the second nfet of the second inverter have increased threshold voltages above the threshold voltages of other remaining transistors in the SRAM memory cell.

16. A semiconductor memory cell for use in memory arrays, comprising:
(a) means to receive a word line signal;
(b) means to receive a true bit line signal;
(c) means to receive a complement bit line signal;
(d) means to cross-couple a first inverter connected to the means to receive the true bit line signal with a second inverter connected to the means to receive a complement bit line signal; and
(e) means to increase the stability of the means to receive the word line signal.

17. The semiconductor memory cell of claim 16, wherein the means to receive a word line signal comprises two transfer nfets, each of which are connected to a word line, the output of first transfer nfet connected to the input of the second inverter and the output of the second transfer nfet connected to the input of the first inverter; and the means to increase the stability of the two transfer nfets comprises increasing the threshold voltage of the two transfer nfets.

18. The semiconductor memory cell of claim 17, further comprising means to increase the threshold voltage of two pulldown nfets, the first pulldown nfet included in the first inverter and the second pulldown nfet included in the second inverter.

19. The semiconductor memory cell of claim 17, wherein the means to increase the threshold voltage of the two transfer nfets comprises implantation of boron ions into a region below a gate of each nfet and between a source and a drain of each nfet prior to gate definition.

20. The semiconductor memory of claim 18, wherein the means to increase the threshold voltage of the two transfer nfets and the two pulldown nfets comprises implantation of boron ions into a region below a gate of each nfet and between a source and a drain of each nfet prior to gate definition without increasing the threshold voltage of any other fets in the semiconductor memory.
